(19) United States
(12) Patent Application Publication
(10) Pub. No.: US 2015/0055423 A1
(43) Pub. Date: Feb. 26, 2015

(54) SEMICONDUCTOR MEMORY APPARATUS

(71) Applicant: SK hynix Inc., Icheon-si Gyeonggi-do (KR)

(72) Inventor: Seung Kyun LIM, Icheon-si Gyeonggi-do (KR)

(73) Assignee: SK hynix Inc., Icheon-si Gyeonggi-do (KR)

(21) Appl. No.: 14/082,860

(22) Filed: Nov. 18, 2013

(30) Foreign Application Priority Data
Aug. 22, 2013 (KR) 10-2013-0099820

(51) Int. Cl. G11C 7/22; G11C 7/12; G11C 7/06

(52) U.S. Cl. CPC G11C 7/22; G11C 7/062; G11C 7/12
USPC 365/189.07; 365/203

(57) ABSTRACT

A data storage unit configured to generate a data voltage; and a data comparison unit including a first input terminal for receiving the data voltage and a second input terminal for receiving a reference voltage, and being configured to compare the voltage levels of the first and second input terminals are included, wherein the data comparison unit compares the voltage levels of the first and second input terminals.

### CROSS-REFERENCES TO RELATED APPLICATION

The present application claims priority under 35 U.S.C. §119(a) to Korean application number 10-2013-0099820, filed on Aug. 22, 2013, in the Korean Intellectual Property Office, which is incorporated herein by reference in its entirety.

### BACKGROUND

1. Technical Field

Various embodiments relate to semiconductor integrated circuit, and more particularly, to a semiconductor memory apparatus.

2. Description of Related Art

A semiconductor memory apparatus is configured to store data and to output stored data.

The semiconductor memory apparatus includes a configuration for receiving stored data from a data storage area and determining the value of the stored data.

The configuration for determining the value of stored data corresponds to a configuration to determine whether the voltage level of the stored data is higher or lower than a reference voltage. Such a configuration to determine the value of data includes an input terminal for receiving a reference voltage, and an input terminal for receiving the voltage level of data.

However, such a method has a disadvantage in that a read operation of determining and outputting the value of stored data to the outside requires a long operating time. This is because, before it is determined whether the voltage level of data is higher or lower than a reference voltage, a period of time, i.e. a loading, occurs until the voltage level of an input terminal receiving the stored data becomes higher or lower than the reference voltage.

### SUMMARY

A semiconductor memory apparatus capable of reducing a period of time required for determining stored data, as compared with the conventional semiconductor memory apparatus is described herein.

In an embodiment of the invention, a semiconductor memory apparatus includes: a data storage unit configured to generate a data voltage; and a data comparison unit including a first input terminal for receiving the data voltage and a second input terminal for receiving a reference voltage, and being configured to compare the voltage levels of the first and second input terminals, wherein the data comparison unit compares the voltage levels of the first and second input terminals.

In an embodiment of the invention, a semiconductor memory apparatus includes: a memory device configured to store data; a current supply unit configured to supply a first current to the memory device; a current mirror unit configured to generate a second current having an amount of current equal to the first current; a voltage conversion unit configured to generate a data voltage having a voltage level corresponding to the amount of current of the second current; a sense amplifier configured to compare the data voltage with the reference voltage to generate a sense amplifier output signal; and a switch configured to pre-charge the data voltage and the reference voltage to have an equal voltage level.

In an embodiment of the invention, a semiconductor memory apparatus includes: a data storage unit configured to generate current corresponding to a resistance value of a memory device, and a data voltage corresponding to the current; and a data comparison unit configured to compare the voltage levels of the data voltage and the reference voltage maintaining the data voltage and the reference voltage to be equal for a predetermined period of time.

In an embodiment of the invention, a semiconductor memory apparatus includes: a data storage unit configured to generate a data voltage; and a data comparison unit comprising a first input terminal configured to receive a data voltage generated by a data storage unit and a second input terminal configured to receive a reference voltage and configured to compare the data voltage to the reference voltage.

### BRIEF DESCRIPTION OF THE DRAWINGS

Features, aspects, and embodiments are described in conjunction with the attached drawings, in which:

FIG. 1 is a block diagram illustrating the configuration of a semiconductor memory apparatus according to an embodiment of the invention;

FIG. 2 is a diagram illustrating the configuration of a controller for of a semiconductor memory apparatus according to an embodiment of the invention, and a timing diagram; and

FIG. 3 is a timing diagram explaining a semiconductor memory apparatus according to an embodiment of the invention.

FIG. 4 is a block diagram illustrating how a semiconductor memory apparatus is incorporated into a memory system according to an embodiment of the invention.

### DETAILED DESCRIPTION

Hereinafter, a semiconductor memory apparatus according to the invention will be described below with reference to the accompanying drawings through various embodiments.

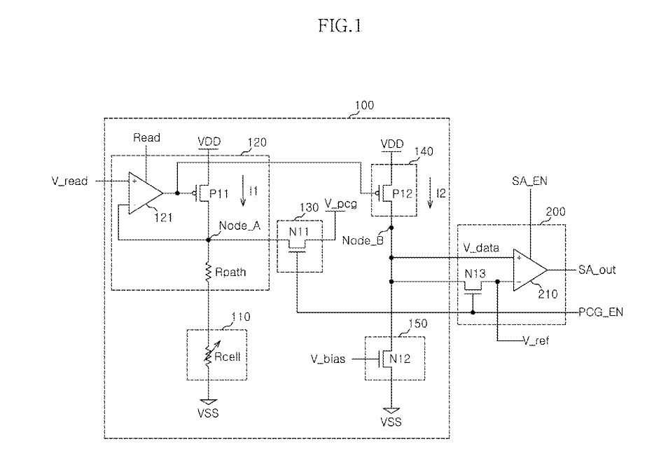

As illustrated in FIG. 1, a semiconductor memory apparatus according to an embodiment of the invention can include a data storage unit 100 and a data comparison unit 200.

The data storage unit 100 generates a data voltage V_data corresponding to stored data on a read operation.

The data storage unit 100 can include a memory device 110, a current supply unit 120, a precharge unit 130, a current mirror unit 140, and a voltage conversion unit 150. The data storage unit 100 may be configured to generate current corresponding to a resistance value of the memory device 110 on a read operation, and generate the data voltage V_data corresponding to the current.

The memory device 110 can include a resistive memory device Rcell. The resistive memory device Rcell has a resistance value which varies depending on a data value input on a write. The memory device 110 may be configured to store data.

The current supply unit 120 applies a constant voltage to the memory device 110 on a read operation. In this case, depending on the resistance value of the memory device 110, the current supply unit 120 changes the amount of current applied to the memory device 110. Accordingly, on a read operation, the current supply unit 120 generates first current I1 applied to the memory device 110 depending on the resistance value of the memory device 110.

The current supply unit 120 can include a comparison unit 121, a first transistor P11, and a resistance path Rpath.

The comparison unit 121 is activated in response to a read signal Read. The activated comparison unit 121 compares a read voltage V_read with the voltage level of a first node Node_A.

The first transistor P11 applies an external voltage VDD to the first node Node_A in response to a comparison result of the comparison unit 121.

The first transistor P11 has a gate which receives a comparison result, i.e. an output signal, of the comparison unit 121, a source which receives an external voltage VDD, and a drain which is electrically coupled to the first node Node_A.

The resistance path Rpath represents a loading of the current supply unit 120, and represents the loading between the current supply unit 120 and the memory device 110. Although it is not shown in the drawing, the loading includes all the loadings of switches and circuits which exist between the current supply unit 120 and the memory device 110. The resistance path Rpath is electrically coupled between the first node Node_A and the memory device 110.

The precharge unit 130 applies a precharge voltage V_pcg to the first node Node_A through which the first current I1 may flow in response to a precharge enable signal PCG_EN.

The precharge unit 130 can include a second transistor N11. The second transistor N11 has a gate which receives the precharge enable signal PCG_EN, a drain which receives the precharge voltage V_pcg, and a source which is electrically coupled to the first node Node_A.

The current mirror unit 140 generates second current I2 having the same amount of current as the first current I1, which is supplied from the current supply unit 120 to the memory device 110. In addition, the current mirror unit 140 may generate second current I2 having the amount of current corresponding to integer multiples of the amount of the first current I1, which is supplied from the current supply unit 120 to the memory device 110.

The current mirror unit 140 can include a third transistor P12. The third transistor P12 has a gate which receives an output signal of the comparison unit 121, a source which receives an external voltage VDD, and a drain which is electrically coupled to a second node Node_B. The current mirror unit 140 applies the second current I2 to the second node Node_B. Since voltages having the same voltage levels as those applied to the gate and source of the first transistor P11 are applied to the gate and source, respectively, of the third transistor P12, the amount of current outputted through the drain of the first transistor P11 is equal to the amount of current outputted through the drain of the third transistor P12. The amount of current of the second current I2 can be determined according to the size ratio of the first transistor P11 to the third transistor P12.

The voltage conversion unit 150 generates a data voltage V_data having a voltage level corresponding to the amount of current of the second current I2.

The voltage conversion unit 150 makes a constant amount of current, corresponding to the voltage level of a bias voltage V_bias flow, from the second node Node_B to a ground terminal VSS. In more detail, when the amount of current of the second current I2 supplied to the second node Node_B is greater than the amount of current flowing to the ground terminal VSS through the voltage conversion unit 150, the voltage level of the data voltage V_data is raised. In contrast, when the amount of current of the second current I2 supplied to the second node Node_B is less than the amount of current flowing to the ground terminal VSS through the voltage conversion unit 150, the voltage level of the data voltage V_data is lowered. Accordingly, the voltage conversion unit 150 can generate the data voltage V_data having a voltage level corresponding to the amount of current of the second current I2.

The voltage conversion unit 150 can include a fourth transistor N12. The fourth transistor N12 has a gate which receives the bias voltage V_bias, a source which is electrically coupled to the second node Node_B, and a drain which is electrically coupled to the ground terminal VSS.

The data comparison unit 200 can include a first input terminal “+” for receiving the data voltage V_data, and a second input terminal “−” for receiving a reference voltage V_ref, and compares the first input terminal “+” and the second input terminal “−”. In this case, the data comparison unit 200 electrically couples the first input terminal “+” with the second input terminal “−” before performing an operation of comparing the voltage levels between the first input terminal “+” and the second input terminal “−”. In addition, the data comparison unit 200 separates the first input terminal “+” and the second input terminal “−” from each other when comparing voltage levels between the first input terminal “+” and the second input terminal “−”. Further, the data comparison unit 200 may be configured to perform a data comparison operation of comparing the voltage levels of the data voltage V_data and the reference voltage V_ref after a precharge operation of maintaining the data voltage V_data and reference voltage V_ref to be equal for a predetermined period of time on a read operation is performed.

The data comparison unit 200 can include a sense amplifier 210 and a switch N13.

The sense amplifier 210 is electrically coupled to the second node Node_B through the first input terminal “+” so as to receive the data voltage V_data through the first input terminal “+”. In addition, the sense amplifier 210 receives the reference voltage V_ref through the second input terminal “−”. In addition, the sense amplifier 210 is activated in response to a sense amplifier enable signal SA_EN. Only when the sense amplifier 210 is activated, the sense amplifier 210 compares the voltage levels of the first and second input terminals “+” and “−”, and generates a sense amplifier output signal SA_out. In this case, the sense amplifier 210 is activated when the sense amplifier enable signal SA_EN is enabled, and is inactivated when the sense amplifier enable signal SA_EN is disabled.

The switch N13 electrically couples or decouples the first and second input terminals “+” and “−” in response to the precharge enable signal PCG_EN. In addition, the switch N13 may be configured to pre-charge the data voltage and the reference voltage to have an equal voltage level in response to the precharge enable signal PCG_EN. The switch N13 may also be configured to maintain the voltage levels of the data voltage and the reference voltage to be equal in response to the precharge enable signal PCG_EN.

The switch N13 includes a fifth transistor N13. The fifth transistor N13 has a gate which receives the precharge enable signal PCG_EN, and a drain and a source which are electrically coupled to the second input terminal “−” and the second node Node_B, respectively. In this case, the fifth transistor N13 electrically couples the first and second input terminals “+” and “−” to each other when the precharge enable signal PCG_EN is enabled, and electrically decouples the first and second input terminals “+” and “−” from each other when the precharge enable signal PCG_EN is disabled. The switch N13 of the data comparison unit 200 is configured to electrically couple the first and second input terminals “+” and “−” to each other before comparing the voltage levels of the first and second input terminals “+” and “−”; and to electrically decouple the first and second input terminals “+” and “−” from each other when the voltage levels of the first and second input terminals are compared with each other.

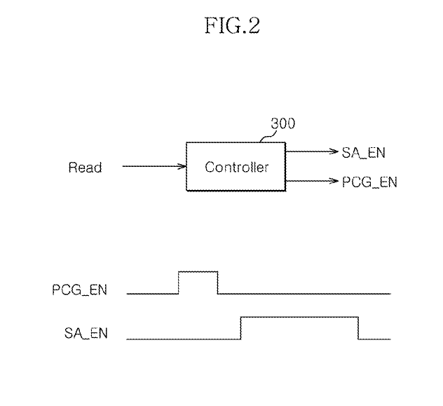

FIG. 2 illustrates a controller 300 which generates the sense amplifier enable signal SA_EN and the precharge enable signal PCG_EN on a read operation, i.e. in response to the read signal Read; and a timing diagram of the sense amplifier enable signal SA_EN and the precharge enable signal PCG_EN.

The controller 300 generates the precharge enable signal PCG_EN enabled for a predetermined period of time when receiving the read signal Read, and enables the sense amplifier enable signal SA_EN when the precharge enable signal PCG_EN is disabled.

The operation of a semiconductor memory apparatus configured as above according to an embodiment of the invention will be described as follows.

Referring to FIG. 2, a read command is inputted to a semiconductor memory apparatus, and thus a read signal Read is generated. The read signal Read is inputted to the controller 300. After receiving the read signal Read, the controller 300 may generate a precharge enable signal PCG_EN enabled for a predetermined period of time. The controller 300 may generate a sense amplifier enable signal SA_EN enabled after the precharge enable signal PCG_EN is disabled.

Referring to FIG. 1, when the read signal Read is inputted, the current supply unit 120 may apply a constant voltage to the memory device 110. In this case, the precharge unit 130 may apply a precharge voltage V_pcg to the first node Node_A of the current supply unit 120 while the precharge enable signal PCG_EN is being enabled. The first transistor P11 increases the voltage level of the first node Node_A up to a target level in response to the output signal of the comparison unit 121. In addition, the precharge unit 130 supplies the precharge voltage V_pcg for the time period during which the precharge enable signal PCG_EN is enabled, thereby assisting the first node Node_A to more rapidly arrive at the target level.

According to the resistance value of the memory device 110, the amount of current flowing from the current supply unit 120 to the ground terminal VSS through the memory device 110 is determined. Current supplied from the current supply unit 120 to the memory device 110 will be referred as a first current I1.

The current mirror unit 140 generates a second current I2 having the same amount of current as the first current I1. The current mirror unit 140 can include a third transistor P12. Since the third transistor P12 and the first transistor P11 receive the same signal through the gates thereof and receive the same voltage through the sources thereof, the third transistor P12 can generate the second current I2 having the same amount of current as the first current I1 supplied through the first transistor P11. In this case, the second current I2 is supplied to the second node Node_B.

The voltage conversion unit 150 makes constant current flow from the second node Node_B to the ground terminal VSS in response to the voltage level of a bias voltage V_bias. Accordingly, when the amount of current flowing from the voltage conversion unit 150 to the ground terminal VSS is greater than the amount of the second current I2 supplied to the second node Node_B, the voltage level of the second node Node_B may be lowered. In contrast, when the amount of current flowing from the voltage conversion unit 150 to the ground terminal VSS is less than the amount of the second current I2 supplied to the second node Node_B, the voltage level of the second node Node_B may be raised. The voltage level of the second node Node_B corresponds to a data voltage V_data.

The precharge enable signal PCG_EN is enabled before the sense amplifier enable signal SA_EN is enabled. Accordingly, the switch N13 of the data comparison unit 200 supplies a reference voltage V_ref to the second node Node_B before the sense amplifier 210 is activated. Accordingly, for a period during which the precharge enable signal PCG_EN is enabled, the voltage level of the second node Node_B, i.e. the data voltage V_data, is equal to the reference voltage V_ref. When the precharge enable signal PCG_EN is disabled, the reference voltage V_ref supplied to the second node Node_B may be cut off, so that the voltage level of the second node Node_B, i.e. the data voltage V_data, begins to change after the precharge enable signal PCG_EN is disabled.

The precharge enable signal PCG_EN is disabled, and the sense amplifier enable signal SA_EN is enabled.

When the sense amplifier enable signal SA_EN is enabled, the sense amplifier 210 may be activated to compare the voltage level of the data voltage V_data inputted to the first input terminal “+” with the voltage level of the reference voltage V_ref applied to the second input terminal “−”.

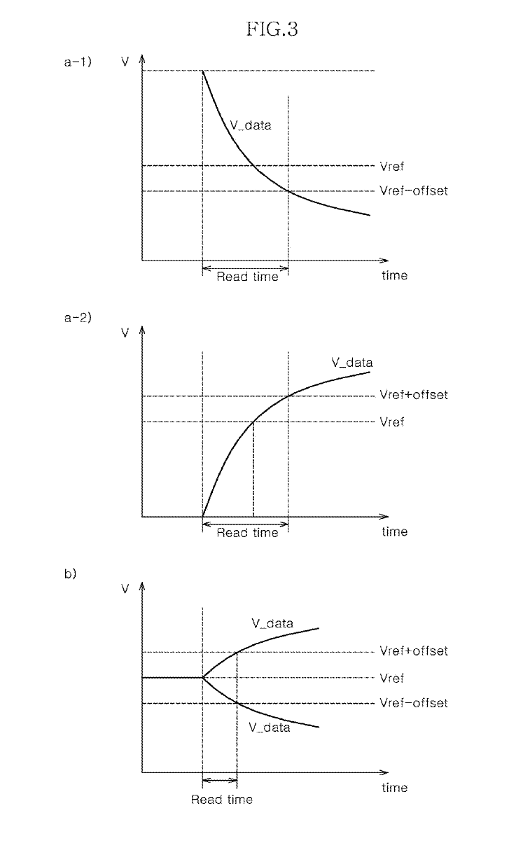

The sensing time, i.e. a read operation time, of the sense amplifier 210 will be described with reference to FIG. 3.

A normal semiconductor memory apparatus sets a data voltage V_data, which is inputted to the first input terminal “+” of a sense amplifier 210, to be higher than a reference voltage V_ref (see “a-1”) or to be lower than the reference voltage V_ref (see “a-2”) in a precharge operation. In this case, a period of time must elapse until a voltage set by the precharge operation becomes lower or higher than the voltage level of the reference voltage V_ref, and also the set voltage must be lower (Vref−offset) or higher (Vref+offset) by the offset of the sense amplifier 210 before the sense amplifier 210 completes a comparison operation to generate an output signal SA_out.

In contrast, the semiconductor memory apparatus according to an embodiment of the invention pre-charges a data voltage V_data with a reference voltage V_ref before the sense amplifier performs a comparison operation, i.e. for a period during which the precharge enable signal PCG_EN is enabled (see “b”). When the precharge enable signal PCG_EN is disabled, the data voltage V_data which is the voltage level of the reference voltage V_ref may be raised or lowered depending on the resistance value of the memory device Rcell. When the data voltage V_data is raised or lowered by an offset, the sense amplifier 210 may compare the data voltage V_data with the voltage level of the reference voltage V_ref, and generates an output signal SA_out. Accordingly, the semiconductor memory apparatus (see “b”) according to an embodiment of the invention pre-charges the data voltage V_data with the reference voltage V_ref before the sense amplifier 210 performs a comparison operation, so that the comparison operation time period of the sense amplifier 210 is shorter than the conventional cases. Accordingly, the semiconductor memory apparatus according to an embodiment of the invention has a shorter data sensing time than the conventional semiconductor memory apparatus, and thus can reduce a read time.

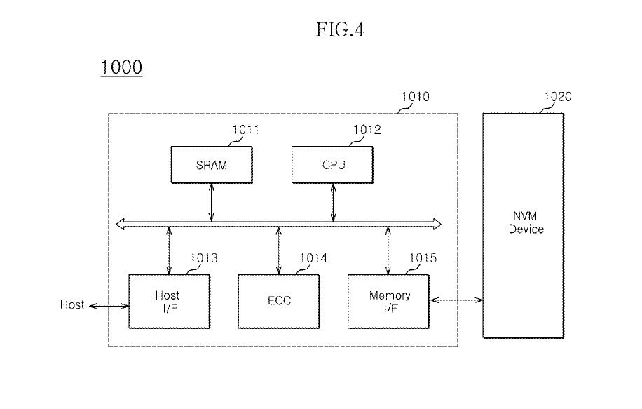

Referring to FIG. 4, a memory system 1000 according to an embodiment of the invention may include a non-volatile memory device 1020 and a memory controller 1010.

The non-volatile memory device 1020 may be configured to include the above-described semiconductor memory apparatus. The memory controller 1010 may be configured to control the non-volatile memory device 1020 in a general operation mode such as a program loop, a read operation or an erase loop.

The memory system 1000 may be a solid state disk (SSD) or a memory card in which the non-volatile memory device 1020 and the memory controller 1010 are combined. The static random-access memory (SRAM) 1011 may function as an operation memory of a central processing unit (CPU) 1012. A host interface 1013 may include a data exchange protocol of a host being coupled to the memory system 1000. An error correction code (ECC) block 1014 may detect and correct errors included in a data read from the non-volatile memory device 1020. A memory interface (I/F) 1015 may interface with the non-volatile memory device 1020. The CPU 1012 may perform the general control operation for data exchange of the memory controller 1010.

The memory system 1000 may be provided as a storage medium with a low error rate and high reliability. A memory system 1000 such as a SSD may include a flash memory device in an embodiment of the invention.

A semiconductor memory apparatus according to the invention reduces a read operation time by reducing a period of time required for determining stored data, thereby increasing the operating speed of the semiconductor memory apparatus.

While certain embodiments have been described above, it will be understood to those skilled in the art that the embodiments described are by way of example only. Accordingly, the apparatus described herein should not be limited based on the described embodiments. Rather, the apparatus described herein should only be limited in light of the claims that follow when taken in conjunction with the above description and accompanying drawings.

What is claimed is:

1. A semiconductor memory apparatus comprising:
a data storage unit configured to generate a data voltage; and
a data comparison unit comprising a first input terminal for receiving the data voltage and a second input terminal for receiving a reference voltage, and being configured to compare the voltage levels of the first and second input terminals,
wherein the data comparison unit compares the voltage levels of the first and second input terminals.

2. The apparatus according to claim 1, wherein the data comparison unit comprises a switch which is configured to electrically couple the first and second input terminals to each other before comparing the voltage levels of the first and second input terminals, and to electrically decouple the first and second input terminals from each other when the voltage levels of the first and second input terminals are compared with each other.

3. The apparatus according to claim 2, further comprising a controller which is configured to generate a precharge enable signal enabled for a predetermined period of time on a read operation, and to enable a sense amplifier enable signal after the precharge enable signal is disabled.

4. The apparatus according to claim 3, wherein the data comparison unit comprises:
a sense amplifier configured to be activated in response to the sense amplifier enable signal, and thus to compare the voltage levels of the first and second input terminals; and
the switch configured to couple or decouple the first and second input terminals in response to the precharge enable signal.

5. A semiconductor memory apparatus comprising:
a memory device configured to store data;
a current supply unit configured to supply a first current to the memory device;
a current mirror unit configured to generate a second current having an amount of current equal to the first current;
is a voltage conversion unit configured to generate a data voltage having a voltage level corresponding to the amount of current of the second current;
a sense amplifier configured to compare the data voltage with the reference voltage to generate a sense amplifier output signal; and
a switch configured to pre-charge the data voltage and the reference voltage to have an equal voltage level.

6. The apparatus according to claim 5, further comprising a precharge unit which is configured to apply a precharge voltage to a node, through which the first current flows, in response to the precharge enable signal.

7. The apparatus according to claim 5, further comprising a controller which is configured to generate the precharge enable signal enabled for a predetermined period of time in response to a read signal, and to enable the sense amplifier enable signal after the precharge enable signal is disabled.

8. The apparatus according to claim 7, wherein the sense amplifier receives the data voltage through a first input terminal and receives the reference voltage through a second input terminal; and
the switch electrically couples or electrically decouples the first input terminal and the second input terminal in response to the precharge enable signal.

9. A semiconductor memory apparatus comprising:
a data storage unit configured to generate current corresponding to a resistance value of a memory device, and a data voltage corresponding to the current; and
a data comparison unit configured to compare the voltage levels of the data voltage and the reference voltage after maintaining the data voltage and the reference voltage to be equal for a predetermined period of time.

10. The apparatus according to claim 9, further comprising a controller which is configured to generate a precharge enable signal enabled for a predetermined period of time in response to a read signal, and to generate a sense amplifier enable signal when the precharge enable signal is disabled.

11. The apparatus according to claim 10, wherein the data comparison unit comprises:
a sense amplifier configured to compare the voltage levels of the data voltage and the reference voltage in response to the sense amplifier enable signal; and
a switch configured to maintain the voltage levels of the data voltage and the reference voltage to be equal in response to the precharge enable signal.

12. The apparatus according to claim 11, wherein the sense amplifier is configured to compare the data voltage inputted to the first input terminal with the voltage level of the reference voltage applied to the second input terminal when the sense amplifier enable signal is enabled, and to be inactivated when the sense amplifier enable signal is disabled.

13. The apparatus according to claim 12, wherein the switch is configured to electrically couple the first input terminal to the second input terminal when the precharge enable signal is enabled, and to electrically decouple the first input terminal from the second input terminal when the precharge enable signal is disabled.

14. A semiconductor memory apparatus comprising:
a data storage unit configured to generate a data voltage; and
a data comparison unit comprising a first input terminal configured to receive a data voltage generated by a data storage unit and a second input terminal configured to receive a reference voltage and configured to compare the data voltage to the reference voltage.

15. The semiconductor memory apparatus of claim 14, wherein the data comparison unit electrically couples the first input terminal to the second input terminal before comparing the data voltage to the reference voltage.

16. The semiconductor memory apparatus of claim 14, wherein the data comparison unit separates the first input terminal from the second input terminal when the data voltage is compared to the reference voltage.

17. The semiconductor memory apparatus of claim 14, wherein the data comparison unit compares the data voltage to the reference voltage when a sense amplifier enable signal is activated.

18. The semiconductor memory apparatus of claim 14, wherein the data comparison unit electrically couples or electrically decouples the first input terminal to the second input terminal in response to a precharge enable signal.

19. The semiconductor memory apparatus of claim 14, further comprising:
a sense amplifier configured to compare the data voltage to the reference voltage when a sense amplifier enable signal is activated.

20. The semiconductor memory apparatus of claim 18, wherein a voltage level of the reference voltage is raised when the precharge enable signal is disabled.
